(19) United States
(12) Patent Application Publication
(10) Pub. No.: US 2025/0233014 A1
(43) Pub. Date: Jul. 17, 2025

(54) SEMICONDUCTOR DEVICE STRUCTURE AND METHOD OF FABRICATING SAME

(71) Applicant: Taiwan Semiconductor Manufacturing Company, LTD., Hsinchu (TW)

(72) Inventors: Jheng-Hong Jiang, Hsinchu (TW); Shing-Huang Wu, Hsinchu (TW); Chia-Wei Liu, Zhubei (TW)

(21) Appl. No.: 18/410,302

(22) Filed: Jan. 11, 2024

(51) Int. Cl. H01L 21/768; H01L 21/311; H01L 23/522; H01L 23/528

(52) U.S. Cl. CPC H01L 21/76829; H01L 21/31144; H01L 21/76819; H01L 21/7684; H01L 21/76843; H01L 21/76877; H01L 23/5226; H01L 23/528

(57) ABSTRACT

A semiconductor device structure and method that utilizes anti-reflection components. The structure includes at least one ramp VIA formed in a VIA isolator layer, at least one anti-reflection component formed on the at least one ramp VIA. A trench isolator layer is formed on the at least one anti-reflection component, and a photoresist is selectively patterned on the trench isolator layer. The trench isolator layer and a portion of the at least one anti-reflection component is etched based upon the selectively patterned photoresist to form a trench metal component hole above the at least one ramp VIA. Thereafter, a trench metal component is formed in the trench metal component hole.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device. Thin film resistors can be made as part of such integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of semiconductor device structure, in accordance with some embodiments.

FIG. 2 is a cross-sectional view of a portion of a semiconductor device structure in accordance with some embodiments.

FIGS. 3A-3S are cross-sectional views of varying stages of fabrication of semiconductor device structure in accordance with some embodiments.

FIGS. 4A-4D are cross-sectional views of varying stages of fabrication of a comparative example of a semiconductor device structure in accordance with some embodiments.

FIGS. 5A-5C are cross-sectional views of varying stages of fabrication of a comparative example of a semiconductor device structure in accordance with some embodiments.

FIG. 6 is a flowchart illustrating a method for fabricating a semiconductor device structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate. The term “directly” may be used to indicate two layers directly contact each other without any layers in between them.

The present disclosure relates to various methods for improving the performance of VIA and trench metal adhesion and stress buffering, especially in back-end-of-line (BEOL) processes. In particular, the present disclosure relates to the implementation of anti-reflection components above ramp VIAs to prevent errors occurring during photoresist patterning of trench metal components. Ramp VIAs include a sloped or angled top portion to increase surface adhesion to trench metal components. This angled/sloped surface can sometimes reflect light when patterning photoresist, resulting in the improper patterning of the photoresist. The anti-reflection components assist in absorbing or deflecting light away from the photoresist during patterning.

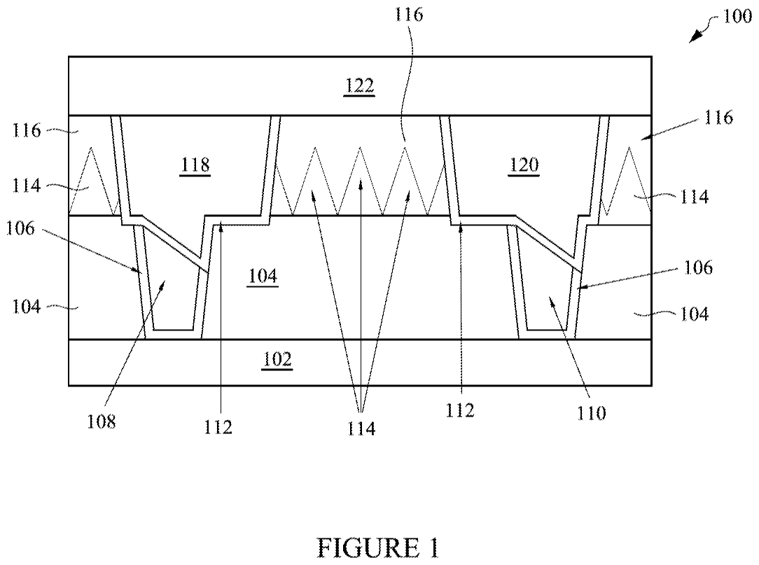

Turning now to FIG. 1, there is shown a cross-sectional view of semiconductor device structure 100 fabricated in accordance with one embodiment of the subject application. As illustrated in FIG. 1, the semiconductor device structure 100 includes a base structure or layer 102. In accordance with varying embodiments, the base structure or layer 102 may correspond to any of a variety of layers of BEOL processing, BEOL metal routing, devices, components, etc., that utilize VIAs for interconnection. The semiconductor device structure 100 further includes a VIA isolator layer 104 positioned on the base layer or structure 102, as shown in FIG. 1. The VIA isolator layer 104 may comprise, for example and without limitation undoped silicate glass (USG), silicon nitride (SiN), phosphosilicate glass (PSG), borophosphosilicate glass (BPSG), fluorosilicate glass (FSG), low-k dielectric material (LK), extreme low-k dielectric material (ELK), Black Diamon (BD) low-k dielectric material, or the like. It will be appreciated that other suitable silicate glasses or materials providing similar optic properties and/or insulative properties may be used in other embodiments. In accordance with some embodiments, the VIA isolator layer 104 may be implemented with a thickness in the range of about 100 angstroms to 500,000 angstroms (100 A to 500 kA).

The semiconductor device structure 100 also includes a VIA glue layer 106, positioned on the VIA isolator layer 104. The VIA glue layer 106 may include, for example and without limitation, titanium nitride (TiN), tantalum nitride (TaN), tungsten (W), titanium (Ti), tantalum (Ta), or the like. In accordance with some embodiments, the VIA glue layer 106 may be implemented with a thickness in the range of about 100 A to 10 kA. As shown in FIG. 1, the semiconductor device structure 100 includes a first ramp VIA 108 and a second ramp VIA 110 formed or positioned in the VIA isolator layer 104. It will be appreciated that the ramp VIAs 108, 110 include a ramp or sloped side profile, which allows for greater surface area to which subsequent components may contact. In some embodiments, the greater surface area provides additional adhesion surface for interface improvement and stress buffering reduction with subsequently deposited metal trench components (118, 120).

The ramp VIA 108 and/or ramp VIA 110 may comprise, for example and without limitation a metal material such as tungsten (W), copper (Cu), aluminum (Al), aluminum copper (AlCu), aluminum silicon copper (AlSiCu), aluminum silicon (AlSi), or the like. It will be appreciated that other suitable metals or metal-alloy materials providing similar conductive properties may be used in other embodiments. In accordance with some embodiments, the ramp VIAs 108, 110 may be implemented with a thickness in the range of about 100 A to 500 kA. It will be appreciated that the depiction in FIG. 1 of two ramp VIAs 108, 110 is intended solely as a nonlimiting example implementation, and the semiconductor device structure 100 may be implemented with any number of ramp VIAs, e.g., one, three, four, five, etc.

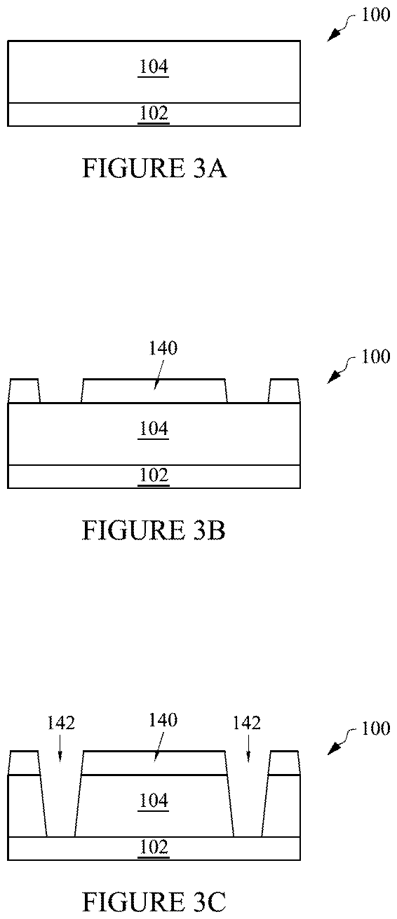

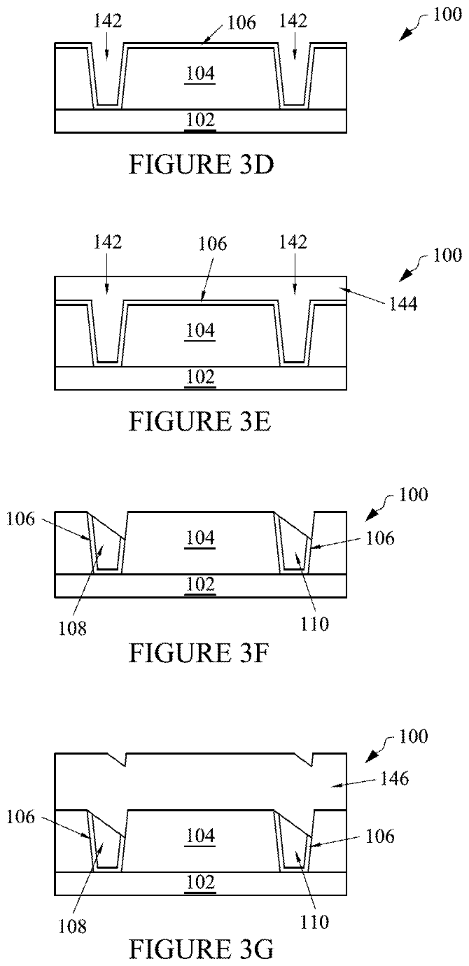

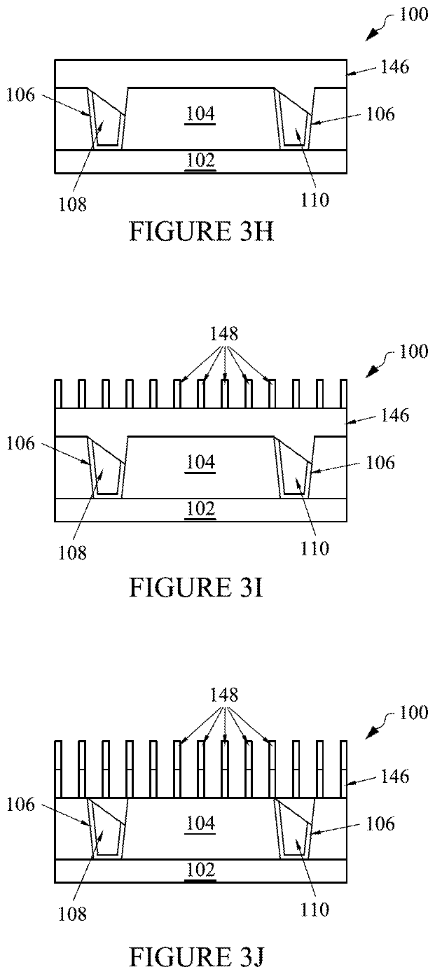

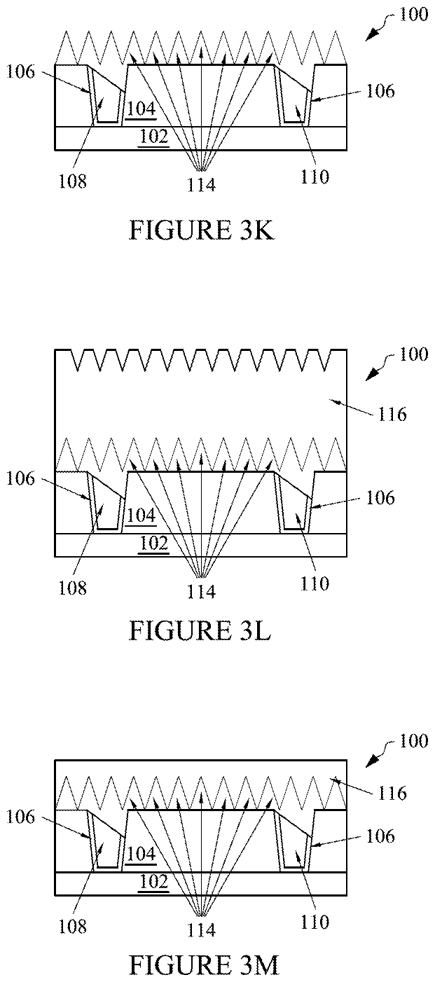

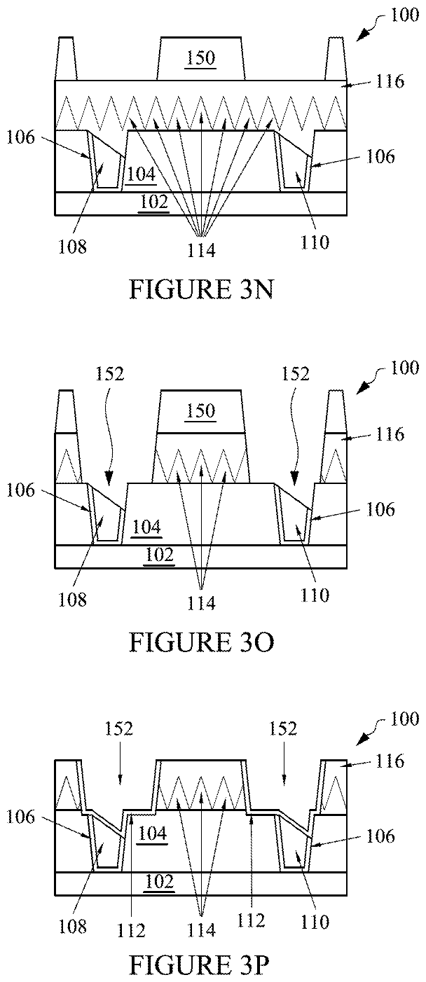

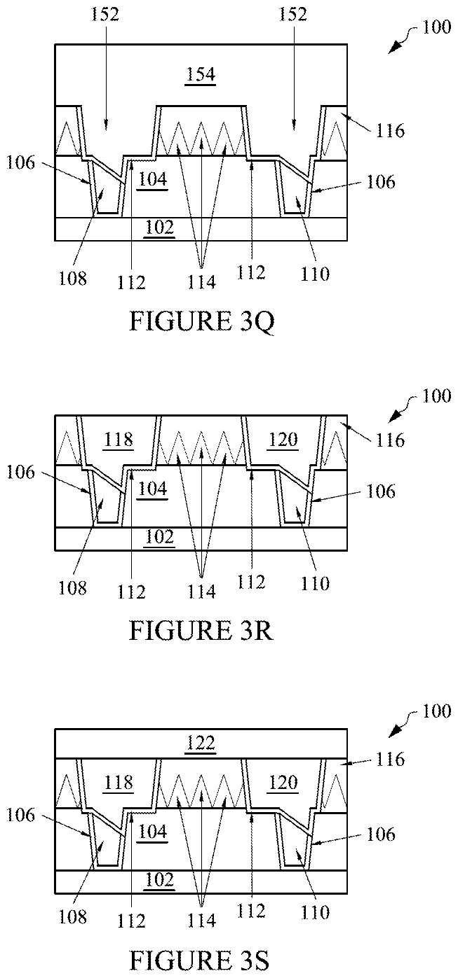

The semiconductor device structure 100 of FIG. 1 further includes one or more anti-reflection components 114 positioned on the via isolator layer 104. The anti-reflection components 114 may be implemented as conical or pyramidal in shape, illustrated in the cross-sectional view of FIG. 1 as the pyramids having bases positioned on the top surface of the VIA isolator layer 104 and apexes extending upward therefrom. In some embodiments, the anti-reflection components 114 are utilized during formation of the semiconductor device structure 100, as discussed in greater detail below. The anti-reflection components 114, in accordance with varying embodiments, may comprise, for example and without limitation, silicon oxynitride (SiON), limitation undoped silicate glass (USG), silicon nitride (SiN), phosphosilicate glass (PSG), fluorosilicate glass (FSG), low-k dielectric material (LK), extreme low-k dielectric material (ELK), Black Diamon (BD) low-k dielectric material, or the like. It will be appreciated that other suitable silicate glasses or materials providing similar optic properties may be used in other embodiments. In some embodiments, the anti-reflection components 114 may comprise one or more layers of the same or different reflection materials. Further discussion of the anti-reflection components 114 is provided below with respect to FIGS. 3A-3S.

A trench isolator layer 116 is positioned on the anti-reflection components 114, as shown in FIG. 1. The trench isolator layer 116 may comprise, for example and without limitation, USG, SiN, PSG, FSG, LK, ELK, BD, or the like. It will be appreciated that other suitable silicate glasses or materials providing similar optic properties and/or insulative properties may be used in other embodiments. In accordance with some embodiments, the trench isolator layer 116 may be implemented with a thickness in the range of about 150 A to 750 kA.

As shown in FIG. 1, a trench glue layer 112 is positioned on the ramp VIAs 108, 110 and the trench isolator layer 116. Trench metal components 118 and 120 are respectively formed or positioned on the ramp VIAs 108, 110, using the trench glue layer 112 as a bonding or adhesion agent. In accordance with some embodiments, the trench glue layer 112 comprises, for example and without limitation, titanium nitride (TiN), tantalum nitride (TaN), tungsten (W), titanium (Ti), tantalum (Ta), or the like. In accordance with some embodiments, the trench glue layer 112 may be implemented with a thickness in the range of about 100 A to 10 kA. In varying embodiments, the trench glue layer 112 and the VIA glue layer 106 may comprise the same or different materials. In other embodiments, the trench glue layer 112 may fully encapsulate the aforementioned trench metal components 118, 120, as illustrated in FIG. 1.

As referenced above, the semiconductor device structure 100 of FIG. 1 further includes a first trench metal component 118 and a second trench metal component 120. As depicted in FIG. 1, the first trench metal component 118 is positioned above the first ramp VIA 108, and the second trench metal component 120 is positioned above the second ramp VIA 110. In accordance with some embodiments, the trench metal components 118-120 may comprise, for example and without limitation, a metal material such as tungsten (W), copper (Cu), aluminum (Al), AlCu, AlSiCu, AlSi, or the like. It will be appreciated that other suitable metals or metal-alloy materials providing similar conductive properties may be used in other embodiments. In accordance with some embodiments, the trench metal components 118-120 may be implemented with a thickness in the range of about 150 A to 750 kA. While shown in FIG. 1 as having two trench metal components, it will be appreciated that any number of trench metal components corresponding to a respective number of ramp VIAs may be used, and the illustration of two trench metal components is intended solely as one example embodiment.

FIG. 1 further depicts a luminous device 122 operatively coupled to the semiconductor device structure 100. As will be appreciated, the luminous device 122 is intended solely as one example device capable of attachment to the trench metal components 118, 120 and trench isolator layer 116. That is, the skilled artisan will appreciate that the semiconductor device structure 100 depicted in FIG. 1 may be fabricated at any point of the BEOL process, i.e., it may be interposed between various components on a chip or wafer, and/or, as shown in FIG. 1, be used to allow subsequent bonding, coupling, attachment, etc., of a separate device. Accordingly, the luminous device 122 referenced in FIG. 1 may be an OLED array, a lighting layer, a transistor layer, a memory layer, a portion of RAM or logic, etc., and the subject application is not limited to the aforementioned luminous device 122.

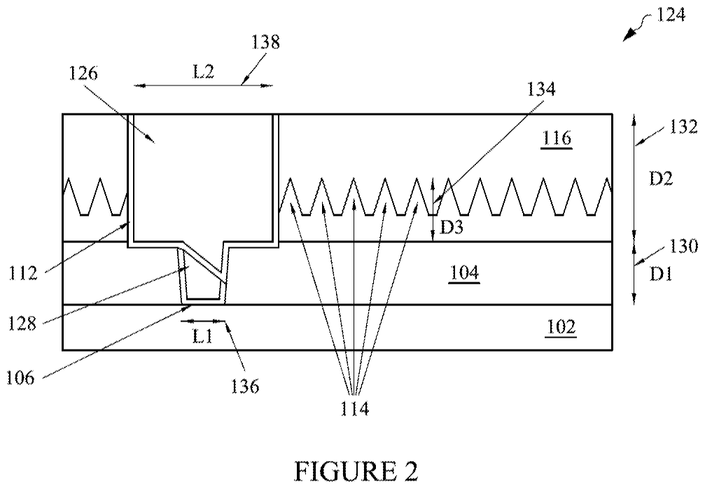

Referring now to FIG. 2, there is shown a cross-sectional view of a portion of a semiconductor device structure 124 in accordance with a second embodiment. As shown in FIG. 2, the semiconductor device structure 124 includes a single trench metal component 126 operatively coupled to a ramp VIA 128. The trench metal component 126 of FIG. 2 is positioned within the trench isolator layer 116 above the VIA isolator layer 104. As illustrated in FIG. 2, a VIA glue layer 106 is formed around the ramp VIA 128, and a trench glue layer 112 is formed around the trench metal component 126, enabling adhesion of the trench metal component 126 with the ramp VIA 128. One or more anti-reflection components 114 are shown in FIG. 2, positioned on the VIA isolator layer 104, interposed between the VIA isolator layer 104 and the trench isolator layer 116.

In accordance with the example embodiment of FIG. 2, the VIA isolator layer 104 may be implemented with a depth (D1) 130 in the range of about 100 A to 500 kA. The trench isolator layer 116 may be implemented with a depth (D2) 132 in the range of about 150 A to 750 kA. In some embodiments, the trench isolator layer depth (D2) 132 is greater than or equal to 1.5 times the VIA isolator depth (D1) (130), i.e., D2≥1.5*D1. As illustrated in FIG. 2, the anti-reflection components 114 may be implemented with a depth (D3) 134 in the range of about 100 A to 500 kA. FIG. 2 further shows the ramp VIA 128 may be implemented with length (L1) 136 in the range of about 10 nm to 500 um. The trench metal component 126 may be implemented with a length (L2) 138 in the range of about 10 nm to 500 um.

Turning now to FIGS. 3A-3S, there are shown cross-sectional views of varying stages of fabrication of a semiconductor device structure 100 in accordance with some embodiments. The patterning of a layer may employ any suitable patterning technique such as a photolithographic patterning technique using deposition of a photoresist layer and selective exposure via a photomask to visible light, ultraviolet light, deep ultraviolet light (i.e., DUV lithography), extreme ultraviolet light (i.e. EUV lithography), or so forth, followed by development of the exposed photoresist and subsequent etching, deposition or other process steps laterally delineated by the developed photoresist. In other embodiments, patterning of an electron-sensitive resist layer may be by way of electron beam exposure (electron beam lithography, i.e., e-beam lithography). The skilled artisan will appreciate that the foregoing are merely illustrative examples.

As shown in FIG. 3A, a VIA isolator layer 104 is formed on an underlying base structure or layer 102. As discussed above, the base structure or layer 102 may correspond to any of a variety of layers of BEOL processing, BEOL metal routing, devices, components, etc., that utilize VIAs for interconnection. As referenced above, the VIA isolator layer 104 may comprise, for example and without limitation undoped silicate glass (USG), silicon nitride (SIN), phosphosilicate glass (PSG), borophosphosilicate glass (BPSG), fluorosilicate glass (FSG), low-k dielectric material (LK), extreme low-k dielectric material (ELK), (BD), or other suitable silicate glasses or materials providing similar optic properties and/or insulative properties may be used in other embodiments. In accordance with some embodiments, formation of the VIA isolator layer 104 may be accomplished via any suitable deposition or layer processes, including, for example and without limitation, deposited by, for example, chemical vapor deposition (CVD), physical vapor deposition (PVD), atomic layer deposition (ALD), sputtering, another deposition process, or any suitable combination thereof. In some embodiments, chemical-mechanical polishing (CMP) may be performed after deposition of the VIA isolator layer 104, resulting in the planar surface shown in FIG. 3A.

A photoresist 140 is then deposited and patterned on the VIA isolator layer 104, as illustrated in FIG. 3B. In some embodiments, the photoresist 140 is applied to the VIA isolator layer 104, after which portions of the photoresist 140 are developed by exposure from a suitable light source to form a pattern thereon. The unexposed portions are then removed, resulting in the patterned photoresist 140 shown in FIG. 3B. Etching is then performed to remove those portions of the VIA isolator layer 104 unprotected by the aforementioned photoresist 140 to form VIA holes 142. Suitable removal processes include, for example and without limitation, an etching process implemented as a dry etching process, a RIE process, a wet etching process, some other etching process, or a combination of the foregoing. FIG. 3C provides an illustration of a stage of fabrication of the semiconductor device structure 100 after formation of the VIA holes 142.

In FIG. 3D, a VIA glue layer 106 is shown deposited on VIA isolator layer 104 and on the surfaces of the VIA holes 142. The VIA glue layer 106 may include, for example and without limitation, titanium nitride (TiN), tantalum nitride (TaN), tungsten (W), titanium (Ti), tantalum (Ta), or the like. In accordance with some embodiments, the VIA glue layer 106 may be implemented with a thickness in the range of about 100 A to 10 kA. In accordance with some embodiments, formation of the VIA glue layer 106 may be accomplished via any suitable deposition or layer processes, including, for example and without limitation, deposited by, for example, chemical vapor deposition (CVD), physical vapor deposition (PVD), atomic layer deposition (ALD), sputtering, another deposition process, or any suitable combination thereof.

A layer of VIA metal material 144 is then deposited on the semiconductor device structure 100, as shown in FIG. 3E. In accordance with some embodiments, the VIA metal material 144 may comprise, for example and without limitation, tungsten (W), copper (Cu), aluminum (Al), AlCu, AlSiCu, AlSi, or the like. It will be appreciated that other suitable metals or metal-alloy materials providing similar conductive properties may be used in other embodiments. As will be appreciated, with the deposition of the VIA metal material 144, the VIA holes 142 are filled. Suitable deposition methods for the VIA metal material 144 may include, for example and without limitation, chemical vapor deposition (CVD), physical vapor deposition (PVD), atomic layer deposition (ALD), electrochemical plating (ECP), sputtering, another deposition process, or any suitable combination thereof. Thereafter, as shown in FIG. 3F, chemical-mechanical polishing (CMP) is performed on the semiconductor device structure 100 to remove portions of the VIA metal material 144 and the VIA glue layer 106, resulting in the formation of ramp VIAs 108 and 110, as shown in FIG. 3F.

A first reflection layer 146 is then formed on the semiconductor device structure 100, as shown in FIG. 3G. The first reflection layer 146 may comprise, for example and without limitation, SiON, USG, SiN, PSG, FSG, LK, ELK, BD, or the like. It will be appreciated that other suitable silicate glasses or materials providing similar optic properties may be used in other embodiments. Formation of the first reflection layer 146 may be accomplished via any suitable deposition method, including, for example and without limitation, CVD, PVD, ALD, sputtering, etc. As shown in FIG. 3G, the first reflection layer 146 is formed on both the VIA isolator layer 104 and on the top (sloped) portion of the ramp VIAs 108, 110.

Chemical-mechanical polishing (CMP) is performed on the semiconductor device structure 100, resulting in the substantially planar surface of the first reflection layer 146 as shown in FIG. 3H. A photoresist 148 is then deposited and patterned on the first reflection layer 146, as shown in FIG. 3I. That is, the photoresist 148 may be deposited and then selectively exposed via a photomask to visible light, ultraviolet light, deep ultraviolet light (i.e., DUV lithography), extreme ultraviolet light (i.e. EUV lithography), or so forth, followed by development of the exposed photoresist, resulting in the patterned photoresist 148 shown in FIG. 3I.

FIG. 3J provides an illustrative cross-sectional view of the semiconductor device structure 100 after etching of the first reflection layer 146 uncovered by the patterned photoresist 148. That is, those portions of the first reflection layer 146 unprotected by the photoresist 148 are removed by, for example and without limitation, an etching process implemented as a dry etching process, a RIE process, a wet etching process, some other etching process, or a combination of the foregoing. As shown in FIG. 3J, columns of the first reflection layer 146 remain after etching, which may then form a base around which the anti-reflection components 114 may be formed. Thus, proceeding to FIG. 3K, there is shown formation of the anti-reflection components 114 via addition of a second reflection layer (not shown) onto the remainder of the first reflection layer 146 after etching and removal of the photoresist 148. In accordance with one embodiment, formation of the anti-reflection components 114 is accomplished using a high-density plasma chemical vapor deposition (HDPCVD) deposition process and/or ion bombardment. That is, the second reflection layer material, which may be the same or different from the first reflection layer 146 is deposited on the remaining portions of the first reflection layer 146. The deposition process forms the conical or pyramidal shaped anti-reflection components 114, as shown in FIG. 3K. It will be appreciated that the use of the HDPCVD process to form the anti-reflection coating of the needle, conical, or pyramidal shaped anti-reflection components 114 assists in avoiding ramp VIA reflection, which induces missing portions of trench isolation (prevents a trench bridge forming), thus improving device performance by reducing the risk of shorting the trench metals due to trench bridging, and thus increasing device yield.

A trench isolator layer 116 is then deposited on the anti-reflection components 114 of the semiconductor device structure 100, as shown in FIG. 3L. In accordance with some embodiments, the trench isolator layer 116 may comprise, for example and without limitation, USG, SiN, PSG, FSG, LK, ELK, BD, or other suitable silicate glasses or materials providing similar optic properties and/or insulative properties may be used in other embodiments. Additionally, it will be appreciated that suitable deposition methods for the trench isolator layer 116 may include, for example and without limitation, CVD, PVD, ALD, sputtering, another deposition process, or any suitable combination thereof. Thereafter, as shown in FIG. 3M, chemical-mechanical polishing (CMP) is performed on the semiconductor device structure 100 to remove portions of the trench isolator layer 116.

In FIG. 3N, a photoresist 150 is deposited and patterned on the trench isolator layer 116 of the semiconductor device structure 100. As shown in FIG. 3N, the photoresist 150 is patterned over the ramp VIAs 108 and 110. As will be appreciated, the photoresist material is deposited on the trench isolator layer 116 and exposure of the photoresist 150 by a suitable light source through a mask forms a pattern of photoresist on the trench isolator layer 116 of protected and unprotected portions thereof. In some embodiments, the anti-reflection components 114 prevent inadvertent patterning by preventing the reflection of light from the angled ramp VIAs 108, 110 into the photoresist 150. Accordingly, after the photoresist 150 is applied and selectively patterned on the trench isolator layer 116, the unexposed portions are then removed, resulting in the patterned photoresist 150 shown in FIG. 3N.

Etching is then performed to remove those portions of the trench isolator layer 116 unprotected by the aforementioned photoresist 150 to form trench metal component cavities or holes 152, as shown in FIG. 3O. As illustrated in FIG. 3O, the portions of the anti-reflection components 114 positioned above the ramp VIAs 108, 110 and above the VIA glue layer 106 are removed within the trench metal component holes 152. Suitable removal processes include, for example and without limitation, an etching process implemented as a dry etching process, a RIE process, a wet etching process, some other etching process, or a combination of the foregoing. It will be appreciated that the portions of the trench isolator layer 116 protected by the photoresist 150 remain on the semiconductor device structure 100, thereby providing an insulator or isolator between the two shown trench metal component holes 152.

A trench glue layer 112 is then formed on the sidewalls and bottom of the trench metal component holes 152, along with the top (angled/sloped) surface of the ramp VIAs 108 and 110, as shown in FIG. 3P. The trench glue layer 112 may include, for example and without limitation, TiN, TaN, W, Ti, Ta, or the like. Formation of the trench glue layer 112 may be accomplished via any suitable deposition or layer processes, including, for example and without limitation, deposited by, for example, CVD, PVD, ALD, sputtering, another deposition process, or any suitable combination thereof.

A trench metal layer 154 is then deposited on the semiconductor device structure 100, as illustrated in FIG. 3Q. In accordance with some embodiments, the trench metal layer 154 may be deposited or formed on the semiconductor device structure 100 by suitable deposition or layer processes, including, for example and without limitation, deposited by, for example, ECP, CVD, PVD, ALD, sputtering, another deposition process, or any suitable combination thereof. As indicated above, the trench metal layer 154 may be implemented as, for example and without limitation, a metal material such as tungsten (W), copper (Cu), aluminum (Al), AlCu, AlSiCu, AlSi, or the like. It will be appreciated that other suitable metals or metal-alloy materials providing similar conductive properties may be used in other embodiments.

Chemical-mechanical polishing (CMP) is then performed on the semiconductor device structure 100 to remove portions of the trench metal layer 154, as shown in FIG. 3R. That is, the trench metal components 118 and 120 are formed in the trench metal component holes 152, bonding with respective ramp VIAs 108, 110 via the trench glue layer 112 formed on the top (sloped/angled) portion of the ramp VIAs 108, 110 at the bottom of the trench metal component holes 152. The semiconductor device structure 100 is then capable of bonding, attachment, etc., to the luminous component 122, as shown in FIG. 3S.

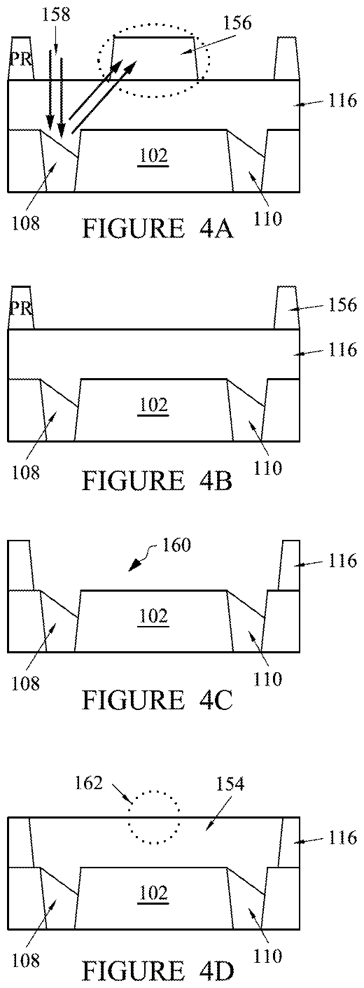

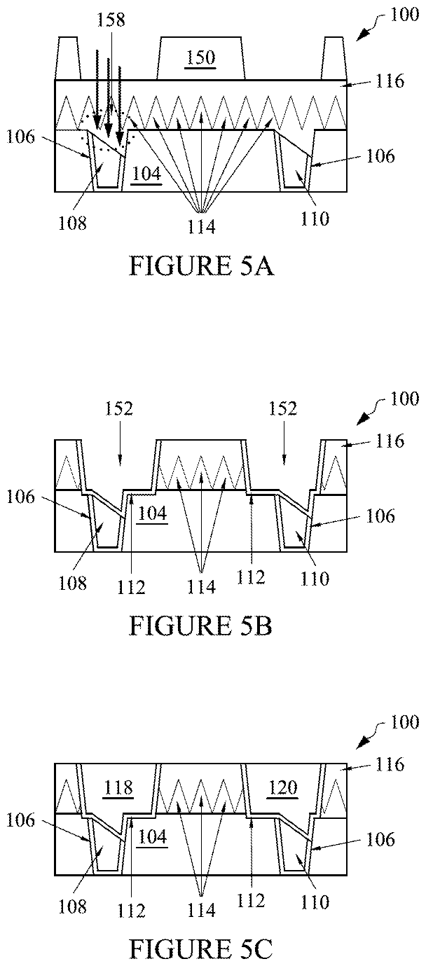

Turning now to FIGS. 4A-4D and FIGS. 5A-5C, there are shown comparative examples of photoresist patterning using the anti-reflection components 114 in accordance with some embodiments. As shown in FIG. 4A, a photoresist 156 is formed on the trench isolation layer 116 and patterned via exposure to a light source 158. As shown in FIG. 4A, the light source 158 is reflected by the top (angled/sloped) surface of the ramp VIA 108 toward the center portion of the photoresist 156. This reflection causes the photoresist 156 to not be cured, as shown in FIG. 4B, whereupon the center portion of the photoresist 156 is no longer present on the trench isolator layer 116 after the photoresist 156 is developed. Thereafter, as shown in FIG. 4C, etching is performed to remove the uncovered portions of the trench isolator layer 116, resulting in the large trench cavity 160. Subsequent deposition of the trench metal layer 154 results in the formation of a trench bridge 162, connecting two (or more) trench metal components that are intended to be separate, as shown in FIG. 4D.

FIGS. 5A-5C provide an illustrative example of a semiconductor device structure 100 in accordance with the methods and apparatus disclosed herein. As shown in FIG. 5A, after deposition of the photoresist 150, exposure via the light source 158 is performed. As depicted in FIG. 5A, the light source 158 is absorbed by the anti-reflection components 114 away from the photoresist 150, resulting in the formation of photoresist 150. As shown in FIG. 5B, the trench metal component holes 152 are separated by a remaining portion of the trench isolator layer 116, unlike the illustration in FIG. 4C. Further, subsequent formation of the trench metal components 118 and 120, as shown in FIG. 5C, illustrates the separation of the trench metal components 118 and 120 and the lack of the undesired trench metal bridge 162 of FIG. 4D.

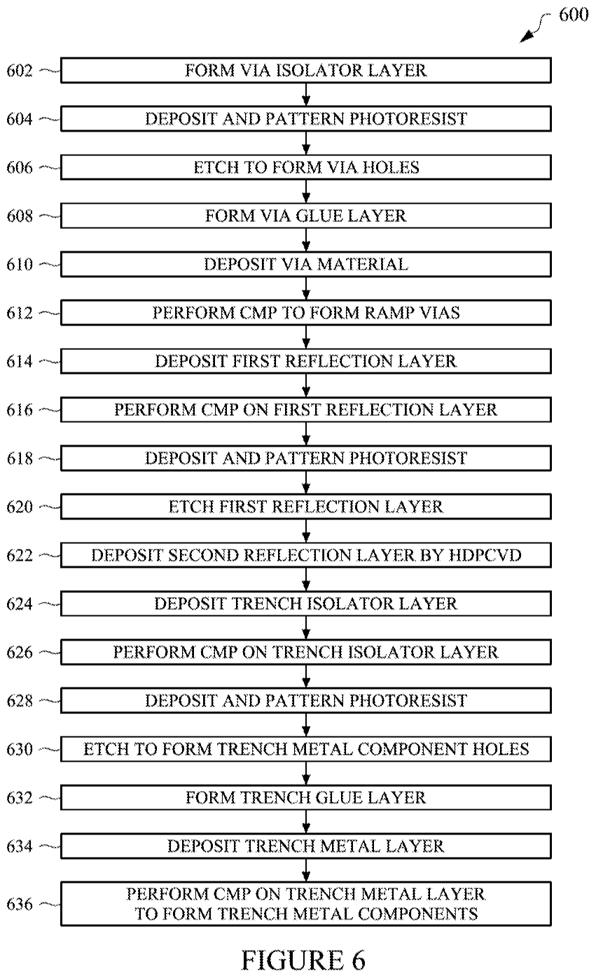

Turning now to FIG. 6, there is shown a flowchart 600 illustrating a method for fabricating a semiconductor device structure 100 in accordance with one embodiment. As shown in FIG. 6, the method 600 begins at step 602, whereupon a VIA isolator layer 104 is deposited on a base structure or layer 102. As indicated above, the VIA isolator layer 104 may comprise any suitable material providing optic and/or insulative properties similar to the following materials, including, for example and without limitation, USG, SIN, PSG, BPSG, FSG, LK, ELK, BD, or the like. In accordance with some embodiments, formation of the VIA isolator layer 104 may be accomplished via any suitable deposition or layer processes, including, for example and without limitation, deposited by, for example, chemical vapor deposition (CVD), physical vapor deposition (PVD), atomic layer deposition (ALD), sputtering, another deposition process, or any suitable combination thereof.

At step 604, a photoresist 140 is deposited and patterned on the VIA isolator layer 104. FIG. 3B provides an illustrative example of the formation of the photoresist 140. Etching is then performed at step 606 to form VIA holes 142 through the VIA isolator layer 104, as shown in FIG. 3C. It will be appreciated that any suitable etching process may be used to remove those portions of the VIA isolator layer 104 not protected by the photoresist 140. After etching, the photoresist 140 is removed, and a VIA glue layer 106 is formed at step 608 on the VIA isolator layer 104 and on the exposed surfaces of the VIA holes 142, as illustrated in FIG. 3D. As discussed above, the VIA glue layer 106 may be implemented with a thickness in the range of about 100 A to 10 kA. In such embodiments, the VIA glue layer 106 may comprise, for example and without limitation, TiN, TaN, W, Ti, Ta, or the like. Formation of the VIA glue layer 106 may be accomplished via any suitable deposition or layer processes, including, for example and without limitation, deposited by, for example, CVD, PVD, ALD, sputtering, another deposition process, or any suitable combination thereof.

At step 610, VIA metal material 144 is deposited on the semiconductor device structure 100, as shown in FIG. 3E. In accordance with one embodiment, the VIA metal material 144 may be deposited via ECP, ALD, CVD, PVD, or the like. Suitable examples of such VIA metal material 144 include, for example and without limitation, W, Cu, Al, AlCu, AlSiCu, AlSi, or the like. It will be appreciated that other suitable metals or metal-alloy materials providing similar conductive properties may be used in other embodiments. As illustrated in FIG. 3E, the VIA metal material 144 adheres or bonds to the VIA glue layer 106. Chemical-mechanical polishing (CMP) is then performed on the semiconductor device structure 100 at step 612 to form ramp VIAs 108, 110. That is, portions of the VIA metal material 144 are removed via CMP, exposing the VIA isolator layer 104 and forming the angled or sloped top portion of the ramp VIAs 108, 110, as shown in FIG. 3F.

At step 614, a first reflection layer 146 is deposited on the semiconductor device structure 100, as illustrated in FIG. 3G. As discussed above, the first reflection layer 146 may comprise, for example and without limitation, SiON, USG, SiN, PSG, FSG, LK, ELK, BD, or the like. It will be appreciated that other suitable silicate glasses or materials providing similar optic properties may be used in other embodiments. Chemical-mechanical polishing (CMP) is then performed on the first reflection layer 146 at step 616, as shown in FIG. 3H.

A photoresist 148 is then deposited and patterned on the first reflection layer 146 at step 618. FIG. 3I illustrates the patterned photoresist 148 in accordance with one embodiment. That is, a layer of photoresist 148 is deposited and then selectively exposed via a photomask to visible light, ultraviolet light, deep ultraviolet light (i.e., DUV lithography), extreme ultraviolet light (i.e. EUV lithography), or so forth, followed by development of the exposed photoresist, resulting in the patterned photoresist 148 as shown in FIG. 3I. The first reflection layer 146 is then etched at step 620, resulting in the intermediate stage of fabrication of the semiconductor device structure 100 shown in FIG. 3J. Accordingly, at step 620, portions of the first reflection layer 146 unprotected by the photoresist 148 are removed by, for example and without limitation, an etching process implemented as a dry etching process, a RIE process, a wet etching process, some other etching process, or a combination of the foregoing. In accordance with one embodiment, columns of the first reflection layer 146 remain after etching, which may then form a base around which the anti-reflection components 114 are formed.

At step 622, a second reflection layer is deposited by HDPCVD on the remaining portions of the first reflection layer 146 to form anti-reflection components 114, as shown in FIG. 3K. As will be appreciated, the HDPCVD deposition process used at step 622 may result in the formation of the conical or pyramidal shaped anti-reflection components 114 illustrated in FIG. 3K. At step 624, a trench isolator layer 116 is deposited on the semiconductor device structure 100 by, for example and without limitation, CVD, PVD, ALD, sputtering, another deposition process, or any suitable combination thereof. FIG. 3L provides an illustrative example of the deposition of the trench isolator layer 116 on the anti-reflection components 114. The trench isolator layer 116, as discussed above, provides insulation between trench metal components 118 and 120, and may be implemented as, for example and without limitation, USG, SiN, PSG, FSG, LK, ELK, BD, or other suitable silicate glasses or materials providing similar optic properties and/or insulative properties may be used in other embodiments. Chemical-mechanical polishing (CMP) is then performed on the semiconductor device structure 100 at step 626 to remove portions of the trench isolator layer 116, as shown in FIG. 3M.

A photoresist 150 is then deposited and selectively patterned on the trench isolator layer 116 at step 628. In accordance with some embodiments, the photoresist material is deposited on the trench isolator layer 116 and exposure of the photoresist 150 by a suitable light source through a mask forms a pattern of photoresist on the trench isolator layer 116 of protected and unprotected portions thereof. In some embodiments, the anti-reflection components 114 prevent inadvertent patterning by preventing the reflection of light from the angled ramp VIAs 108, 110 into the photoresist 150. Accordingly, after the photoresist 150 is applied and patterned on the trench isolator layer 116, the unexposed portions are then removed, resulting in the patterned photoresist 150 shown in FIG. 3N.

At step 630, etching is performed to remove portions of the trench isolator layer 116 and the anti-reflection components 114 above the ramp VIAs 108, 110, unprotected by the patterned photoresist 150, thereby forming trench metal component holes 152. FIG. 3O provides an illustrative example of the formed trench metal component holes 152. The aforementioned etching performed at step 630 may comprise, for example and without limitation, a dry etching process, a RIE process, a wet etching process, some other etching process, or a combination of the foregoing. It will be appreciated that the portions of the trench isolator layer 116 protected by the photoresist 150 remain on the semiconductor device structure 100, thereby providing an insulator or isolator between the two shown trench metal component holes 152.

At step 632, a trench glue layer 112 is formed, e.g., deposited, on the semiconductor device structure 100. Any suitable deposition or layer processes, including, for example and without limitation, deposited by, for example, CVD, PVD, ALD, sputtering, another deposition process, or any suitable combination thereof may be used to form the trench glue layer 112. As shown in FIG. 3P, the trench glue layer 112 is formed on the sidewalls and bottom of the trench metal component holes 152, along with the top (angled/sloped) surface of the ramp VIAs 108, 110. In accordance with some embodiments, the trench glue layer 112 may be implemented as, for example and without limitation, TiN, TaN, W, Ti, Ta, or the like. A trench metal layer 154 is then deposited or formed on the semiconductor device structure 100 at step 634, filling in the trench metal component holes 152, as shown in FIG. 3Q. As indicated above, the trench metal layer 154 may be implemented as, for example and without limitation, a metal material such as W, Cu, Al, AlCu, AlSiCu, AlSi, or the like, and may be formed by, for example, ECP, CVD, PVD, ALD, sputtering, another deposition process, or any suitable combination thereof. Thereafter, at step 636, chemical-mechanical polishing (CMP) is performed on the semiconductor device structure 100 to remove portions of the trench metal layer 154. FIG. 3R provides an illustration of the formation of the trench metal components 118 and 120 in the trench metal component holes 152, bonding with respective ramp VIAs 108, 110 via the trench glue layer 112 formed on the top (sloped/angled) portion of the ramp VIAs 108, 110 at the bottom of the trench metal component holes 152.

As will be understood, ramp VIAs, may inadvertently reflect light during exposure, causing portions of the photoresist to form in a manner unintended. For example, while the ramp VIAs improve adhesion with trench metals, the angle of the top portion of the ramp VIA also reflects light. This reflected light may negatively impact patterning of the photoresist. After such patterning, portions of the trench isolator layer may be removed during subsequent etching that are intended to remain. A result may be the formation of a trench metal bridge, i.e., a bridge of trench metal material connecting two or more trench metal components. The addition of the anti-reflection components, however, prevents the photoresist from being improperly patterned, thereby preventing formation of such a bridge. In some embodiments, the anti-reflection components deflect or absorb light which would otherwise be reflected by the top of the ramp VIA to the photoresist, thereby preventing unintended patterning of the photoresist.

In accordance with a first embodiment, there is provided a method for fabricating a semiconductor device structure that includes depositing a first reflection layer on a VIA isolator layer, with the VIA isolator including at least one ramp VIA. The method further includes performing chemical-mechanical polishing on the first reflection layer, and depositing a photoresist on the first reflection layer after performing chemical-mechanical polishing. The method also includes patterning the photoresist and etching the first reflection layer, resulting in columns of the first reflection layer. In addition, the method includes depositing a second reflection layer on the columns of the first reflection layer by high-density plasma chemical vapor deposition (HDPCVD) to form anti-reflection components corresponding to the columns. The method also includes forming a trench isolator layer on the anti-reflection components, and selectively patterning a photoresist on the trench isolator layer. The pattern is aligned with the at least one ramp VIA. Additionally, the method includes etching through the trench isolator layer and the anti-reflection components based on the selectively patterned photoresist to form a trench metal component hole above the at least one ramp VIA. Thereafter, the method includes forming a trench metal component in the trench metal component hole.

In accordance with a second embodiment, there is provided a method for fabricating a semiconductor device structure. The method includes forming at least one ramp VIA in a VIA isolator layer, and forming at least one anti-reflection component on the at least one ramp VIA. The method further includes forming a trench isolator layer on the at least one anti-reflection component, and selectively patterning a photoresist on the trench isolator layer based on the at least one anti-reflection component. The method also includes etching through the trench isolator layer and the at least one anti-reflection component based upon the selectively patterned photoresist to form a trench metal component hole above the at least one ramp VIA. Thereafter, the method includes forming a trench metal component in the trench metal component hole.

In accordance with a third embodiment, there is provided a semiconductor device structure. The semiconductor device structure includes a VIA isolator layer and at least one ramp VIA positioned in the VIA isolator layer. The semiconductor device structure further includes at least one anti-reflection component positioned on the VIA isolator layer above the at least one ramp VIA, and a trench isolator layer formed on the at least one anti-reflection component. The semiconductor device further includes at least one trench metal component positioned in the trench isolator layer contacting the at least one ramp VIA.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device structure, comprising:
depositing a first reflection layer on a VIA isolator layer, the VIA isolator layer including at least one ramp VIA;
performing chemical-mechanical polishing on the first reflection layer;
depositing a photoresist on the first reflection layer subsequent to the chemical-mechanical polishing;
patterning the photoresist on the first reflection layer;
etching the first reflection layer into a plurality of columns in accordance with the patterned photoresist;
depositing a second reflection layer on the plurality of columns of the first reflection layer by high-density plasma chemical vapor deposition (HDPCVD), to form a plurality of anti-reflection components corresponding to the plurality of columns;
forming a trench isolator layer on the plurality of anti-reflection components;
selectively patterning a photoresist on the trench isolator layer;
etching through the trench isolator layer and the plurality of anti-reflection components to form a trench metal component hole above the at least one ramp VIA; and
forming a trench metal component in the trench metal component hole.

2. The method of claim 1, wherein selectively patterning the photoresist on the trench isolator layer further comprises:
depositing a layer of photoresist on the trench isolator layer; and
exposing the layer of photoresist to a light source, wherein the at least one anti-reflection component prevents inadvertent exposure of the photoresist from the ramp VIA.

3. The method of claim 1, wherein the at least one anti-reflection component is conical, pyramidal or needle in shape.

4. The method of claim 1, wherein forming the trench isolator layer further comprises:
depositing a trench isolator material on the VIA isolator layer; and
performing chemical-mechanical polishing on the trench isolator material.

5. The method of claim 1, wherein forming the trench metal component further comprises:
forming a trench glue layer in the trench metal component hole;
depositing a trench metal material in the trench metal component hole; and
performing chemical-mechanical polishing on the deposited trench metal material to form the trench metal component.

6. The method of claim 1, wherein a depth of the trench isolator layer is greater than or equal to 1.5 times a depth of the VIA isolator layer.

7. The method of claim 1, wherein the first reflection layer and the second reflection layer comprise different materials.

8. The method of claim 1, wherein the first reflection layer and the second reflection layer comprise a same material.

9. A method of fabricating a semiconductor device structure, comprising:
forming at least one ramp VIA in a VIA isolator layer;
forming at least one anti-reflection component on the at least one ramp VIA;
forming a trench isolator layer on the at least one anti-reflection component;
selectively patterning a photoresist on the trench isolator layer;
etching through the trench isolator layer and a portion of the at least one anti-reflection component to form a trench metal component hole above the at least one ramp VIA; and
forming a trench metal component in the trench metal component hole.

10. The method of claim 9, wherein selectively patterning the photoresist further comprises:
depositing a layer of photoresist on the trench isolator layer; and
exposing the layer of photoresist to a light source, wherein the at least one anti-reflection component prevents inadvertent exposure of the photoresist from the ramp VIA.

11. The method of claim 9, wherein forming the at least one anti-reflection component further comprises:
depositing a first reflection layer on the VIA isolator layer;
patterning the first reflection layer into a plurality of columns; and
depositing a second reflection layer on the plurality of columns of the first reflection layer by high-density plasma chemical vapor deposition (HDPCVD).

12. The method of claim 9, wherein the at least one anti-reflection component is conical, pyramidal or needle in shape.

13. The method of claim 9, wherein forming the at least one ramp VIA further comprises:
patterning a photoresist on the VIA isolator layer;
etching the VIA isolator layer in accordance with the patterned photoresist to form at least one VIA hole;
forming a VIA glue layer in the at least one VIA hole;
depositing a VIA material in the at least one VIA hole; and
performing chemical-mechanical polishing to form the at least one ramp VIA.

14. The method of claim 9, wherein a depth of the trench isolator layer is greater than or equal to 1.5 times a depth of the VIA isolator layer.

15. The method of claim 9, wherein forming the at least one trench metal component further comprises:
forming a trench glue layer in the trench metal component hole;
depositing a trench metal material in the trench metal component hole; and
performing chemical-mechanical polishing on the deposited trench metal material to form the trench metal component.

16. A semiconductor device structure, comprising:
a VIA isolator layer;
at least one ramp VIA disposed in the VIA isolator layer;
at least one anti-reflection component formed above the at least one ramp VIA on the VIA isolator layer;
a trench isolator layer formed on the at least one anti-reflection component; and
at least one trench metal component disposed in the trench isolator layer contacting the at least one ramp VIA.

17. The semiconductor device structure of claim 16, wherein the at least one anti-reflection component comprises a first reflection layer and a second reflection layer, the second reflection layer formed by high-density plasma chemical vapor deposition (HDPCVD).

18. The semiconductor device structure of claim 16, wherein the at least one anti-reflection component is conical, pyramidal or needle in shape.

19. The semiconductor device structure of claim 16, further comprising:
a VIA glue layer disposed between the at least on ramp VIA and the VIA isolator layer; and
a trench glue layer disposed between the at least one trench metal component and the trench isolator layer.

20. The semiconductor device structure of claim 16, wherein a depth of the trench isolator layer is greater than or equal to 1.5 times a depth of the VIA isolator layer.
